(19) United States
(12) Patent Application Publication
(10) Pub. No.: US 2011/0068881 A1
(43) Pub. Date: Mar. 24, 2011

(54) ACOUSTIC WAVE FILTER

(76) Inventors: Joji FUJIWARA, Osaka (JP); Tetsuya Tsurunari, Osaka (JP); Hiroyuki Nakamura, Osaka (JP)

(21) Appl. No.: 12/882,254

(22) Filed: Sep. 15, 2010

(30) Foreign Application Priority Data
Sep. 18, 2009 (JP) 2009-216645

(51) Int. Cl. H03H 9/64

(52) U.S. Cl. 333/195

(57) ABSTRACT

An acoustic wave filter includes a first IDT electrode, a second IDT electrode, and a third IDT electrode. The first IDT electrode includes a first signal electrode finger connected to the unbalanced terminal, and a first ground electrode finger. The second IDT electrode includes a second signal electrode finger connected to a first balanced terminal, and a second ground electrode finger. The third IDT electrode includes a third signal electrode finger connected to the second balanced terminal, and a third ground electrode finger. A dummy electrode finger connected neither to the unbalanced terminal nor to the ground is provided on the second IDT electrode side in the first IDT electrode. Thus, the degree of balance between balanced terminals can be improved.

### BACKGROUND OF THE INVENTION

1. Field of the Invention

The present invention relates to an acoustic wave filter.

2. Background Art

As shown in FIG. 13, conventional acoustic wave filter 130 includes unbalanced terminal 137, first balanced terminal 138a for outputting a signal of an opposite phase to that of unbalanced terminal 137, and second balanced terminal 138b for outputting a signal of the same phase as that of unbalanced terminal 137. Furthermore, acoustic wave filter 130 includes first IDT (Inter Digital Transducer) electrode 131, second IDT electrode 132, third IDT electrode 133, fourth IDT electrode 134 and fifth IDT electrode 135. First IDT electrode 131 is electrically connected to unbalanced terminal 137. Second IDT electrode 132 is electrically connected to first balanced terminal 138a. Third IDT electrode 133 is electrically connected to second balanced terminal 138b. Furthermore, acoustic wave filter 130 includes reflectors 136a and 136b formed so as to sandwich first to fifth IDT electrodes 131 to 135 from both sides in the acoustic wave propagation direction.

With such a configuration, based on an unbalanced signal input from unbalanced terminal 137, a pair of balanced signals having opposite phases to each other are output from first balanced terminal 138a and second balanced terminal 138b, respectively.

Note here that an example of conventional art information related to the invention of this application includes Japanese Patent Application Unexamined Publication No. 2003-309452.

In conventional acoustic wave filter 130, the degree of balance between a signal output from first balanced terminal 138a and a signal output from second balanced terminal 138b is not good.

### SUMMARY OF THE INVENTION

An acoustic wave filter of the present invention includes an unbalanced terminal, a first balanced terminal, a second balanced terminal, a first IDT electrode, a second IDT electrode, and a third IDT electrode. The first balanced terminal outputs a signal of an opposite phase to that of the unbalanced terminal. The second balanced terminal outputs a signal of the same phase as that of the unbalanced terminal. The first IDT electrode includes first signal electrode fingers electrically connected to the unbalanced terminal and first ground electrode fingers electrically connected to the ground, and the first signal electrode fingers and the first ground electrode fingers are disposed alternately. The second IDT electrode includes second signal electrode fingers electrically connected to the first balanced terminal and second ground electrode fingers electrically connected to the ground, and the second signal electrode fingers and the second ground electrode fingers are disposed alternately. The third IDT electrode includes third signal electrode fingers electrically connected to the second balanced terminal and third ground electrode fingers electrically connected to the ground, and the third signal electrode fingers and the third ground electrode fingers are disposed alternately. A dummy electrode finger electrically connected neither to the unbalanced terminal nor to the ground is provided on the second IDT electrode side in the first IDT electrode.

This configuration can improve the degree of balance between a signal output from the first balanced terminal and a signal output from the second balanced terminal.

### BRIEF DESCRIPTION OF THE DRAWINGS

FIG. 1 is a view illustrating a configuration of an acoustic wave filter in accordance with an embodiment of the present invention.

FIG. 2A is a graph showing bandpass characteristics of the acoustic wave filter of the embodiment of the present invention and a conventional acoustic wave filter.

FIG. 2B is an enlarged view of a part surrounded by broken line T1 of FIG. 2A.

FIG. 2C is a graph showing a phase difference of the acoustic wave filter of the embodiment of the present invention and a phase difference of a conventional acoustic wave filter.

FIG. 2D is a graph showing an amplitude difference of the acoustic wave filter of the embodiment of the present invention and an amplitude difference of a conventional acoustic wave filter.

FIG. 3 is a view illustrating a configuration of an acoustic wave filter of a comparative example.

FIG. 4A is a graph showing bandpass characteristics of an acoustic wave filter of the comparative example and a conventional acoustic wave filter.

FIG. 4B is an enlarged view of a part surrounded by broken line T2 of FIG. 4A.

FIG. 4C is a graph showing a phase difference of an acoustic wave filter of the comparative example and a phase difference of a conventional acoustic wave filter.

FIG. 4D is a graph showing an amplitude difference of an acoustic wave filter of the comparative example and an amplitude difference of a conventional acoustic wave filter.

FIG. 5 is a view illustrating a configuration of another acoustic wave filter of a comparative example.

FIG. 6A is a graph showing bandpass characteristics of another acoustic wave filter of the comparative example and a conventional acoustic wave filter.

FIG. 6B is an enlarged view of a part surrounded by broken line T3 of FIG. 6A.

FIG. 6C is a graph showing a phase difference of another acoustic wave filter of the comparative example and a phase difference of a conventional acoustic wave filter.

FIG. 6D is a graph showing an amplitude difference of another acoustic wave filter of the comparative example and an amplitude difference of a conventional acoustic wave filter.

FIG. 7 is a view illustrating a configuration of another acoustic wave filter of a comparative example.

FIG. 8A is a graph showing a bandpass characteristic of another acoustic wave filter of the comparative example and a bandpass characteristic of a conventional acoustic wave filter.

FIG. 8B is an enlarged view of a part surrounded by broken line T4 of FIG. 8A.

FIG. 8C is a graph showing a phase difference of another acoustic wave filter of the comparative example and a phase difference of a conventional acoustic wave filter.

FIG. 8D is a graph showing an amplitude difference of another acoustic wave filter of the comparative example and an amplitude difference of a conventional acoustic wave filter.

FIG. 9 is a view illustrating a configuration of another acoustic wave filter having another configuration in accordance with the embodiment of the present invention.

FIG. 10 is a view illustrating a configuration of another acoustic wave filter in accordance with the embodiment of the present invention.

FIG. 11 is a view illustrating a configuration of another acoustic wave filter in accordance with the embodiment of the present invention.

FIG. 12 is a view illustrating a configuration of another acoustic wave filter in accordance with the embodiment of the present invention.

FIG. 13 is a view illustrating a configuration of a conventional acoustic wave filter.

### DETAILED DESCRIPTION OF THE INVENTION

Hereinafter, an embodiment of the present invention is described with reference to the drawings. However, the present invention is not necessarily limited by this embodiment.

### Embodiment

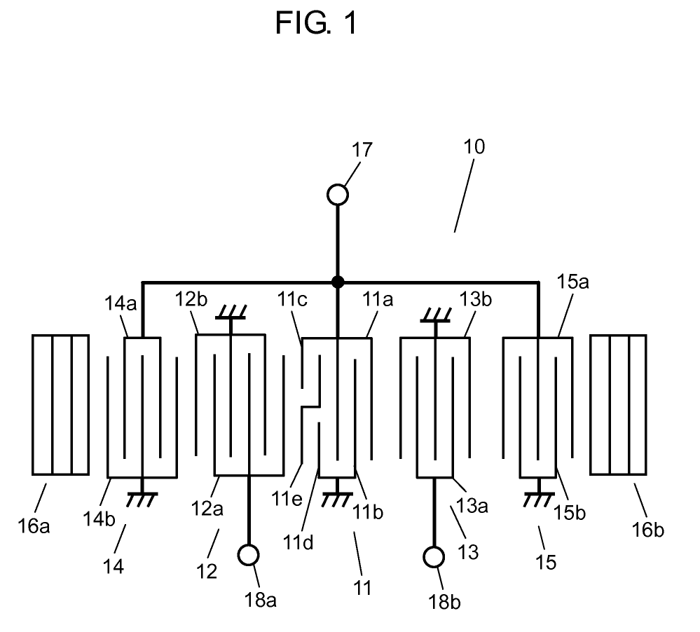

FIG. 1 is a view showing a configuration of acoustic wave filter 10 in accordance with an embodiment of the present invention. This embodiment describes acoustic wave filter 10 that is a longitudinally coupled double mode filter using five IDT electrodes as an example.

In FIG. 1, acoustic wave filter 10 includes unbalanced terminal 17, first balanced terminal 18a, second balanced terminal 18b, and first IDT electrode 11, fourth IDT electrode 14 and fifth IDT electrode 15 electrically connected to unbalanced terminal 17. Furthermore, acoustic wave filter 10 includes second IDT electrode 12 electrically connected to first balanced terminal 18a, and third IDT electrode 13 electrically connected to second balanced terminal 18b. Furthermore, acoustic wave filter 10 includes reflectors 16a and 16b disposed so as to sandwich first to fifth IDT electrodes 11 to 15 from both sides in the acoustic wave propagation direction.

First IDT electrode 11 includes first signal electrode fingers 11a electrically connected to unbalanced terminal 17, and first ground electrode fingers 11b electrically connected to the ground.

Second IDT electrode 12 includes second signal electrode fingers 12a electrically connected to first balanced terminal 18a and second ground electrode fingers 12b electrically connected to the ground.

Third IDT electrode 13 includes third signal electrode fingers 13a electrically connected to second balanced terminal 18b and third ground electrode fingers 13b electrically connected to the ground.

Fourth IDT electrode 14 includes fourth signal electrode fingers 14a electrically connected to unbalanced terminal 17 and fourth ground electrode fingers 14b electrically connected to the ground.

Fifth IDT electrode 15 includes fifth signal electrode fingers 15a electrically connected to unbalanced terminal 17 and fifth ground electrode fingers 15b electrically connected to the ground.

Furthermore, first to fifth IDT electrodes 11 to 15 and reflectors 16a and 16b are provided on a piezoelectric substrate (not shown) along the acoustic wave propagation direction. The piezoelectric substrate is made of a single crystal piezoelectric material having a plate thickness of about 100 μm to 350 μm. For example, the piezoelectric substrate is a substrate of quartz, lithium tantalate, lithium niobate, or potassium niobate.

Furthermore, first signal electrode finger 11a and second signal electrode finger 12a are formed adjacent to each other. First signal electrode finger 11a and third ground electrode 13b are formed adjacent to each other.

This configuration allows a signal input from unbalanced terminal 17 to pass through a range from 2.11 GHz to 2.17 GHz, which is a reception band of Band 1 of the UMTS standard, and also allows first balanced terminal 18a and second balanced terminal 18b to output signals of opposite phases to each other.

However, a configuration other than acoustic wave filter 10 also allows first balanced terminal 18a and second balanced terminal 18b to output signals of opposite phases to each other. For example, a configuration in which first signal electrode finger 11a and second signal electrode finger 12a are formed adjacent to each other, and first ground electrode finger 11b and third signal electrode 13a are formed adjacent to each other may be employed. In this configuration, similar to acoustic wave filter 10, since first signal electrode finger 11a and second signal electrode finger 12a are adjacent to each other, the present invention can be applied by providing dummy electrode finger 11e described below.

In acoustic wave filter 10 of this embodiment, as shown in FIG. 1, dummy electrode finger 11e electrically connected neither to unbalanced terminal 17 nor to the ground is provided on second IDT electrode 12 side in first IDT electrode 11.

As shown in FIG. 1, outermost electrode finger 11c (a first outermost electrode finger) on second signal electrode fingers 12a side in first signal electrode fingers 11a and outermost electrode finger 11d (a second outermost electrode finger) on second signal electrode fingers 12a side in first ground electrode fingers 11b are formed to be short in length so that they are not engaged with each other. Dummy electrode finger 11e is formed so as to have electrode parts facing two outermost electrode fingers 11c and 11d, respectively.

Note here that first to fifth signal electrode fingers 11a to 15a, first to fifth ground electrode fingers 11b to 15b and dummy electrode finger 11e have an electrode thickness of about 0.1 μm to 0.5 μm. These are made of, for example, a simple metal from at least one of aluminum, copper, silver, gold, titanium, tungsten, platinum, chromium, and molybdenum, or an alloy including these metals as a main component or a configuration in which these metals are laminated. Note here that dummy electrode finger 11e may be made of materials that are different from materials of first to fifth signal electrode fingers 11a to 15a and first to fifth ground electrode fingers 11b to 15b.

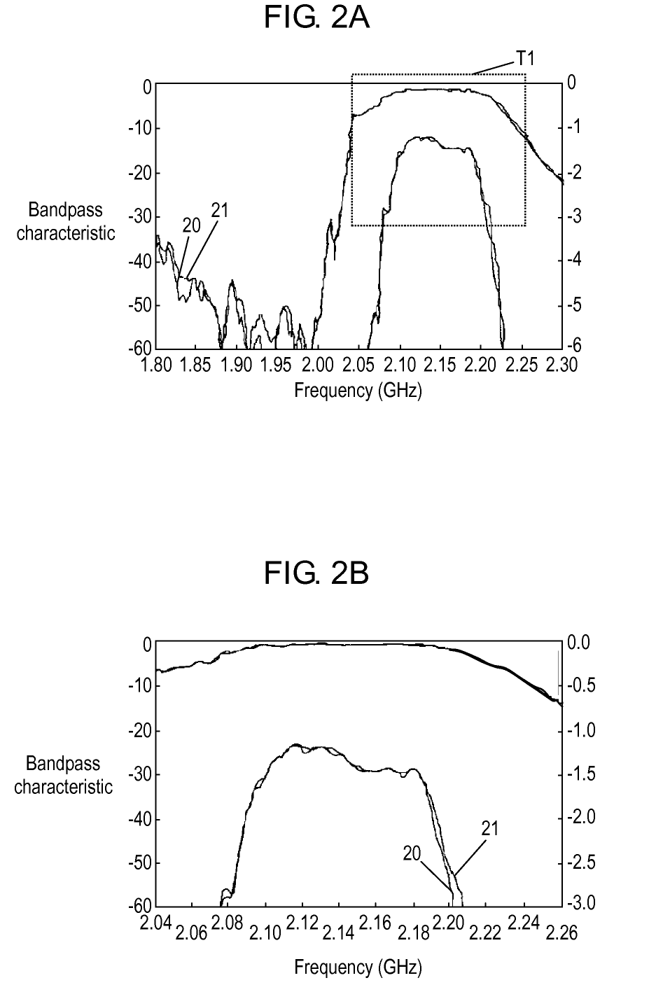

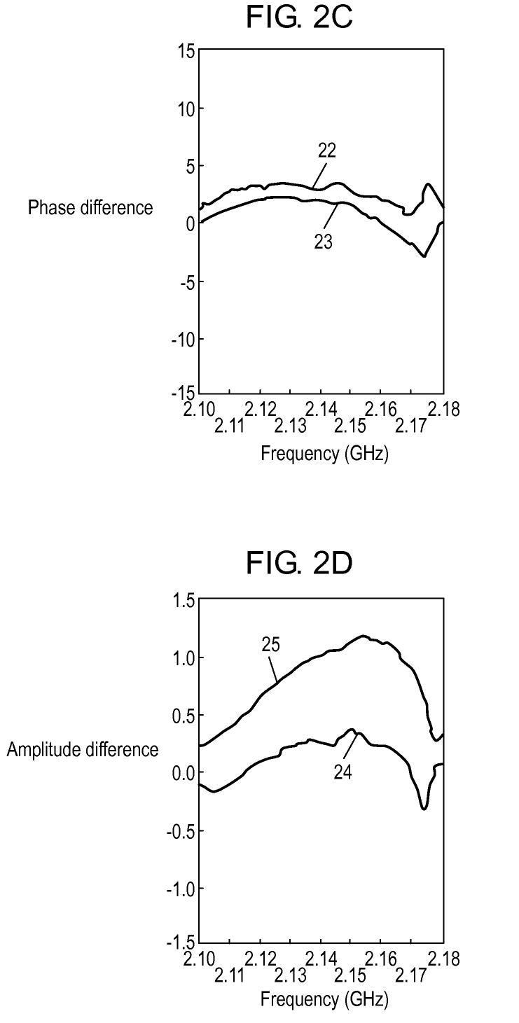

FIG. 2A is a graph showing bandpass characteristic 20 of acoustic wave filter 10 of this embodiment and bandpass characteristic 21 of conventional acoustic wave filter 130. FIG. 2B is an enlarged view of a part surrounded by broken line T1 of FIG. 2A. FIG. 2C is a graph showing phase difference 22 between first balanced terminal 18a and second balanced terminal 18b in acoustic wave filter 10 and phase difference 23 between first balanced terminal 138a and second balanced terminal 138b of conventional acoustic wave filter 130. FIG. 2D is a graph showing amplitude difference 24 between first balanced terminal 18a and second balanced terminal 18b in acoustic wave filter 10 and amplitude difference 25 between first balanced terminal 138a and second balanced terminal 138b in conventional acoustic wave filter 130.

As shown in FIGS. 2A to 2C, bandpass characteristic 20 and phase difference 22 of acoustic wave filter 10 maintain the same level as bandpass characteristic 21 and phase difference 23 of conventional acoustic wave filter 130. Furthermore, as shown in FIG. 2D, amplitude difference 24 is significantly improved as compared with amplitude difference 25 of conventional acoustic wave filter 130. That is to say, the degree of balance between a signal output from first balanced terminal 18a in acoustic wave filter 10 and a signal output from second balanced terminal 18b is significantly improved.

The cause of deterioration of the degree of balance in conventional acoustic wave filter 130 and cause of improvement of the degree of balance in acoustic wave filter 10 of this embodiment are thought to be as follows. In general, in a longitudinally coupled double mode filter, a propagation path from the unbalanced terminal to the first balanced terminal and a propagation path from an unbalanced terminal to a second balanced terminal are not electrically the same as each other. That is to say, in conventional acoustic wave filter 130, first signal electrode finger 131a in first IDT electrode 131 and second signal electrode finger 132a in second IDT electrode 132 are formed adjacent to each other. Furthermore, first signal electrode finger 131a in first IDT electrode 131 and third ground electrode finger 133b in third IDT electrode 133 are formed adjacent to each other.

With this configuration, signals of opposite phase to each other can be output from first balanced terminal 138a and second balanced terminal 138b. However, difference occurs between propagation paths. In conventional acoustic wave filter 130, due to the difference in the propagation paths, a phase difference may occur between a signal output from first balanced terminal 138a and a signal output from second balanced terminal 138b.

Acoustic wave filter 10 of this embodiment suppresses the difference between the propagation path from unbalanced terminal 17 to first balanced terminal 18a and the propagation path from unbalanced terminal 17 to second balanced terminal 18b by dummy electrode finger 11e.

Thus, in acoustic wave filter 10, by providing dummy electrode finger 11e in a predetermined position, the degree of balance between a signal output from first balanced terminal 18a and a signal output from second balanced terminal 18b can be improved.

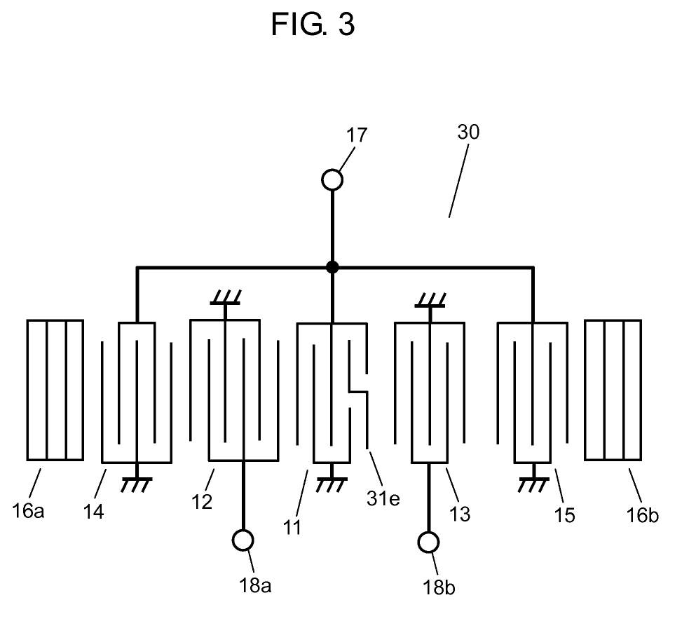

Hereinafter, the fact that the degree of balance between the signal output from first balanced terminal 18a and the signal output from second balanced terminal 18b cannot be improved when dummy electrode finger 11e is provided in a position that is different from the position in acoustic wave filter 10 is described with reference to FIGS. 3 to 8D.

FIG. 3 is a view illustrating a configuration of an acoustic wave filter of a comparative example of the present invention. Acoustic wave filter 30 shown in FIG. 3 includes dummy electrode finger 31e electrically connected neither to unbalanced terminal 17 nor to the ground on third IDT electrode 13 side in first IDT electrode 11. Acoustic wave filter 30 is different from acoustic wave filter 10 shown in FIG. 1 in that dummy electrode finger 31e is provided on third IDT electrode 13 side.

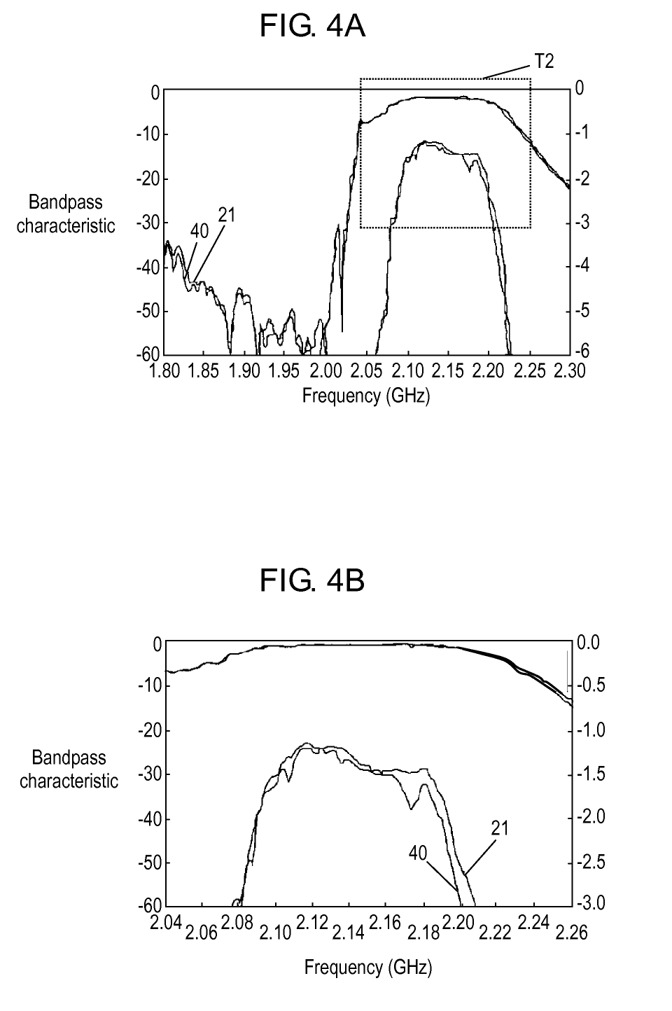

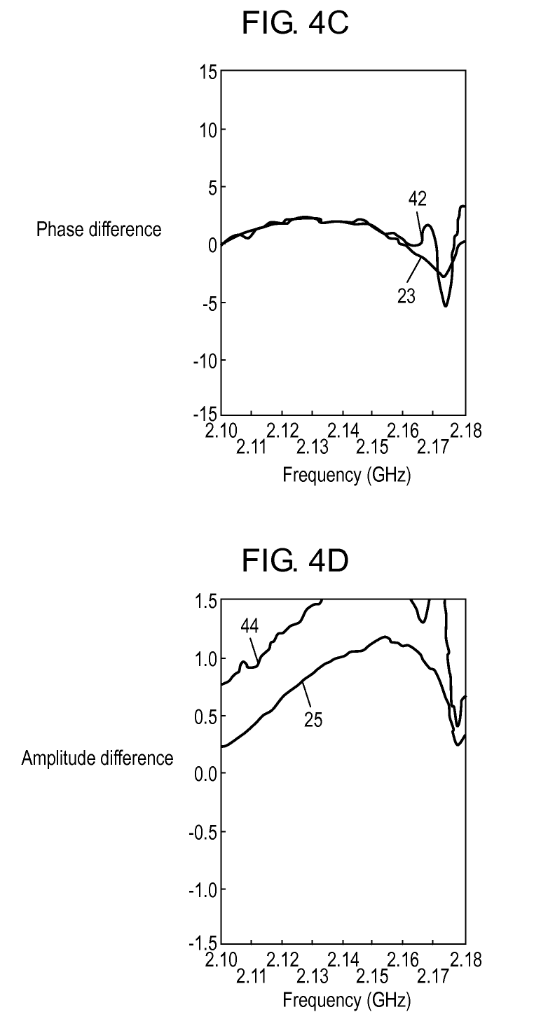

FIG. 4A is a graph showing bandpass characteristic 40 of acoustic wave filter 30 and bandpass characteristic 21 of conventional acoustic wave filter 130. FIG. 4B is an enlarged view of a part surrounded by broken line T2 of FIG. 4A. FIG. 4C is a graph showing phase difference 42 between first balanced terminal 18a and second balanced terminal 18b in acoustic wave filter 30 and phase difference 23 between first balanced terminal 138a and second balanced terminal 138b of conventional acoustic wave filter 130. FIG. 4D is a graph showing amplitude difference 44 between first balanced terminal 18a and second balanced terminal 18b in acoustic wave filter 30 and amplitude difference 25 between first balanced terminal 138a and second balanced terminal 138b in conventional acoustic wave filter 130.

From the measurement results shown in FIGS. 4A to 4D, as compared with conventional acoustic wave filter 130, in acoustic wave filter 30, phase difference 42 is maintained at the same level as that of conventional phase difference 23 as shown in FIG. 4C. However, as shown in FIGS. 4B and 4D, bandpass characteristic 40 and amplitude difference 44 are not improved.

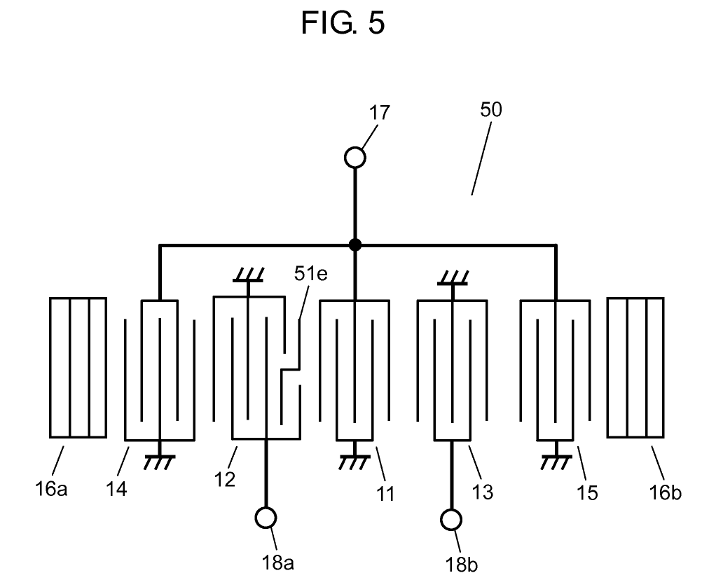

FIG. 5 is a view illustrating a configuration of another acoustic wave filter of a comparative example of the present invention. Acoustic wave filter 50 shown in FIG. 5 includes dummy electrode finger 51e electrically connected neither to first unbalanced terminal 18a nor to the ground on first IDT electrode 11 side in second IDT electrode 12. Acoustic wave filter 50 is different from acoustic wave filter 10 shown in FIG. 1 in that dummy electrode finger 51e is provided such that it is included in second IDT electrode 12.

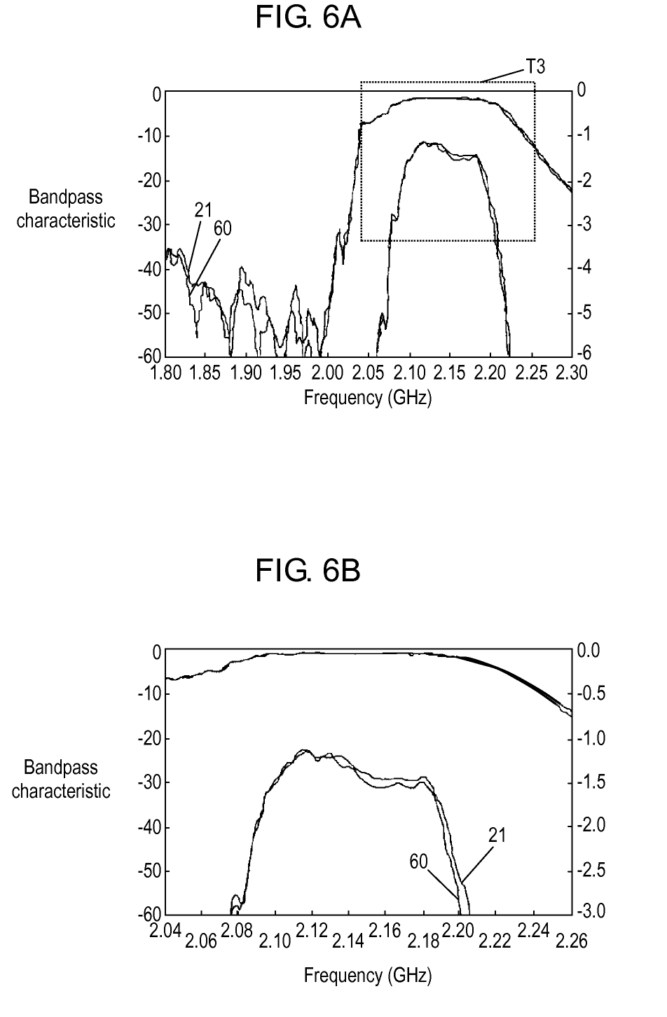

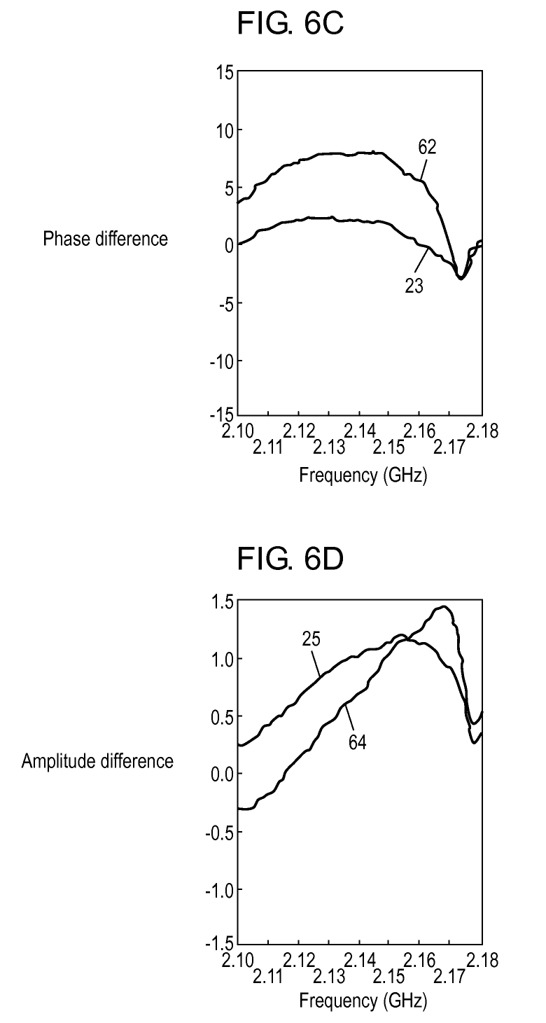

FIG. 6A is a graph showing bandpass characteristic 60 of acoustic wave filter 50 and bandpass characteristic 21 of conventional acoustic wave filter 130. FIG. 6B is an enlarged view of a part surrounded by broken line T3 of FIG. 6A. FIG. 6C is a graph showing phase difference 62 between first balanced terminal 18a and second balanced terminal 18b in acoustic wave filter 50 and phase difference 23 between first balanced terminal 138a and second balanced terminal 138b of conventional acoustic wave filter 130. FIG. 6D is a graph showing amplitude difference 64 between first balanced terminal 18a and second balanced terminal 18b in acoustic wave filter 50 and amplitude difference 25 between first balanced terminal 138a and second balanced terminal 138b in conventional acoustic wave filter 130.

From the measurement results shown in FIGS. 6A to 6D, in acoustic wave filter 50, as shown in FIGS. 6B, 6C and 6D, bandpass characteristic 60, phase difference 62 and amplitude difference 64 are not improved as compared with conventional acoustic wave filter 130.

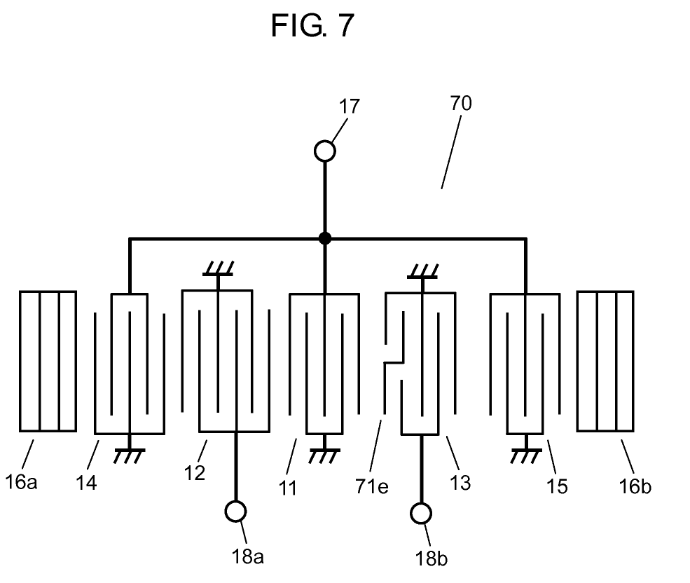

FIG. 7 is a view illustrating a configuration of another acoustic wave filter of a comparative example of the present invention. Acoustic wave filter 70 shown in FIG. 7 includes dummy electrode finger 71e electrically connected neither to second unbalanced terminal 18b nor to the ground on first IDT electrode 11 side in third IDT electrode 13. Acoustic wave filter 70 is different from acoustic wave filter 10 shown in FIG. 1 in that dummy electrode finger 71e is provided such that it is included in third IDT electrode 13.

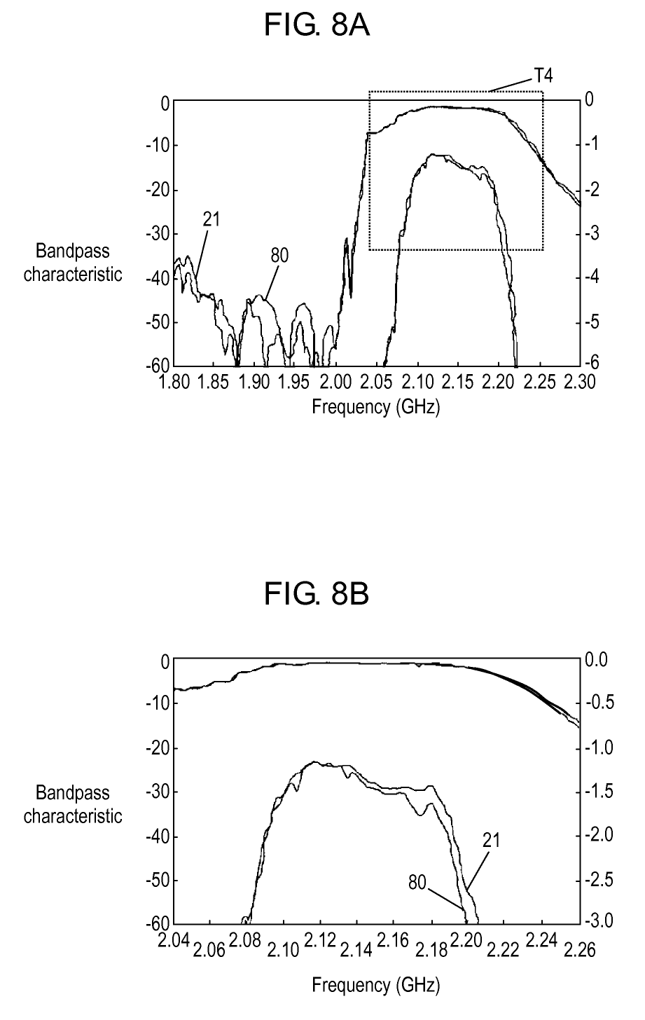

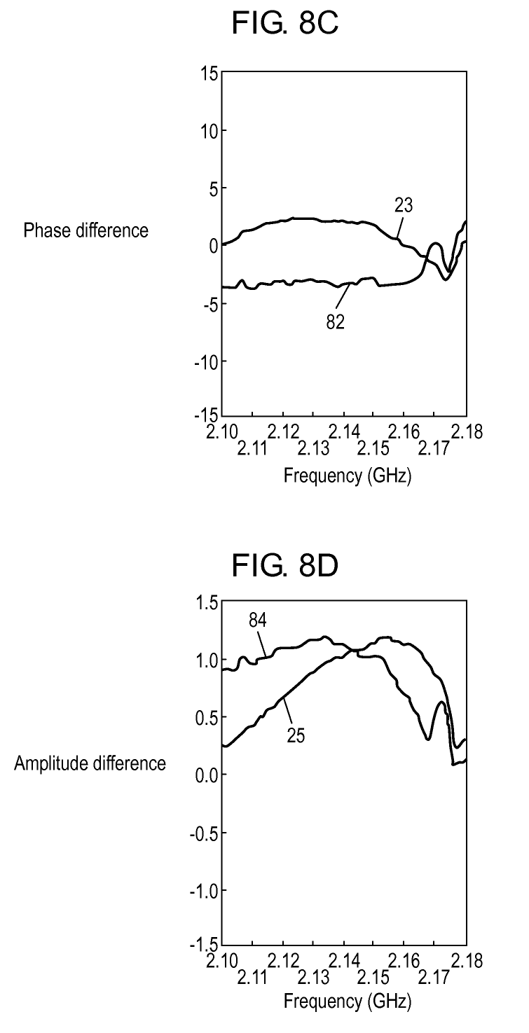

FIG. 8A is a graph showing bandpass characteristic 80 of acoustic wave filter 70 and bandpass characteristic 21 of conventional acoustic wave filter 130. FIG. 8B is an enlarged view of region T4 of FIG. 8A. FIG. 8C is a graph showing phase difference 82 between first balanced terminal 18a and second balanced terminal 18b in acoustic wave filter 70 and phase difference 23 between first balanced terminal 138a and second balanced terminal 138b of conventional acoustic wave filter 130. FIG. 8D is a graph showing amplitude difference 84 between first balanced terminal 18a and second balanced terminal 18b in acoustic wave filter 70 and amplitude difference 25 between first balanced terminal 138a and second balanced terminal 138b in conventional acoustic wave filter 130.

From the measurement results shown in FIGS. 8A to 8D, in acoustic wave filter 70, bandpass characteristic 80, phase difference 82 and amplitude difference 84 are not improved as compared with conventional acoustic wave filter 130 as shown in FIGS. 8B, 8C and 8D.

From the above-mentioned results, as shown in FIG. 1, with the configuration in which dummy electrode finger 11e is provided on second IDT electrode 12 side in first IDT electrode 11, the degree of balance between a signal output from first balanced terminal 18a and a signal output from second balanced terminal 18b can be improved.

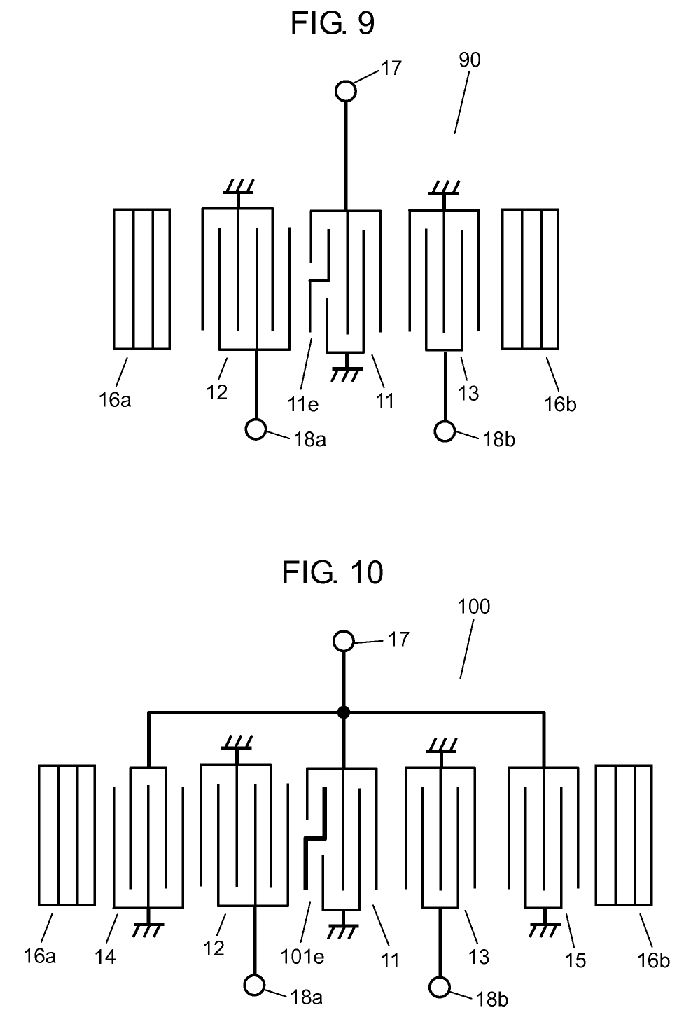

Note here that in this embodiment, acoustic wave filter 10 that is a longitudinally coupled double mode filter using five IDT electrodes is described as an example. The acoustic wave filter may be a longitudinally coupled double mode filter in which the number of IDT electrodes to be used is other than five. FIG. 9 is a view illustrating a configuration of an acoustic wave filter having another configuration in accordance with the embodiment of the present invention. Acoustic wave filter 90 shown in FIG. 9 is a longitudinally coupled double mode filter using three IDT electrodes. By configuring acoustic wave filter 90 as shown in FIG. 9, the degree of balance between a signal output from first balanced terminal 18a and a signal output from second balanced terminal 18b can be improved and the size of the acoustic wave filter can be reduced.

Note here that it is more desirable that a dummy electrode finger is provided only on second IDT electrode 12 side as shown in FIG. 1 rather than a configuration in which a dummy electrode finger is provided at both end portions of first IDT electrode 11. By providing the dummy electrode finger on only one side, it is possible to suppress the difference between the propagation path from unbalanced terminal 17 to first balanced terminal 18a and the propagation path from unbalanced terminal 17 to second balanced terminal 18b.

Note here that the shape of a dummy electrode finger is not necessarily limited to the shape of dummy electrode finger 11e shown in FIG. 1. The dummy electrode finger has any shapes as long as it can adjust the propagation path of a signal. For example, as acoustic wave filter 100 shown in FIG. 10, the width of electrode finger of dummy electrode finger 101e may be made to be larger than that of the other electrode fingers. Thus, even when a difference between a propagation path from unbalanced terminal 17 to first balanced terminal 18a and a propagation path from unbalanced terminal 17 to second balanced terminal 18b is large, the difference of the propagation path can be suppressed easily. On the contrary, when the difference of the propagation paths is small, the width of an electrode finger of dummy electrode finger 101e may be made to be smaller than the width of the other electrode fingers.

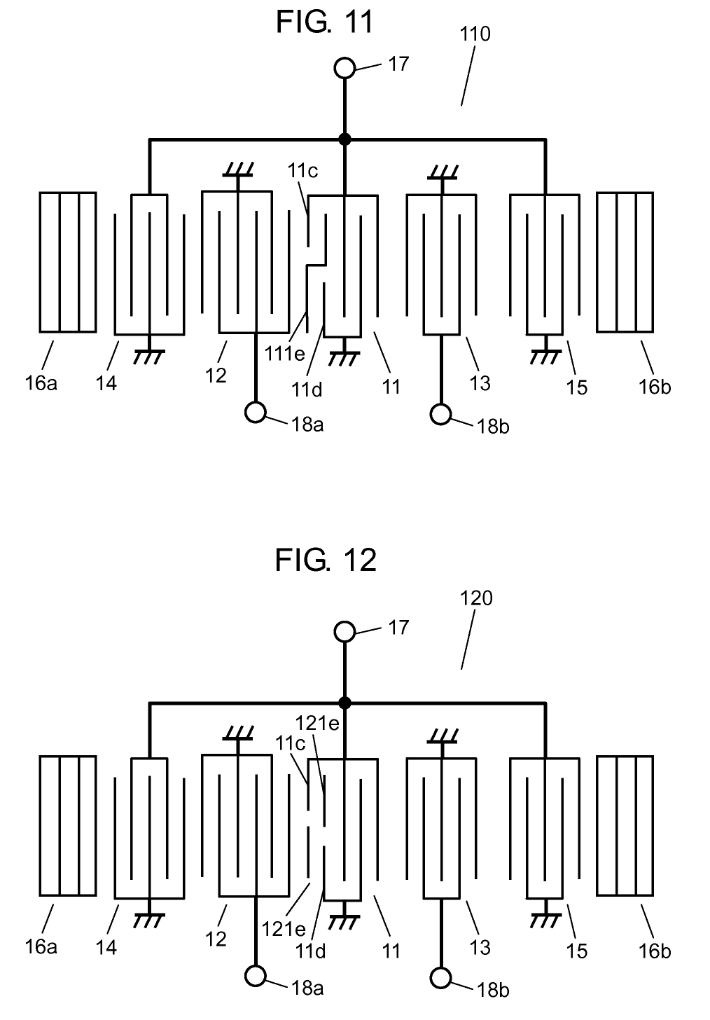

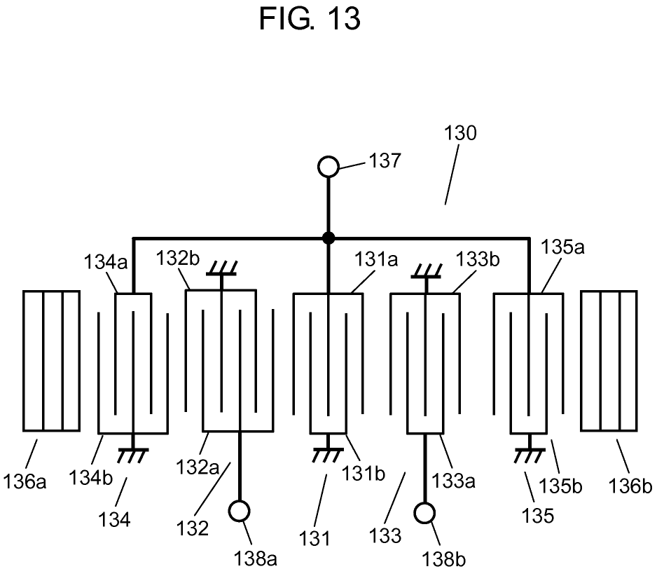

Furthermore, as acoustic wave filter 110 shown in FIG. 11, in dummy electrode finger 111e, a length facing outermost electrode finger 11c and a length facing outermost electrode finger 11d may be asymmetric. Also with this configuration, the difference of the propagation paths can be adjusted.

Furthermore, as in acoustic wave filter 120 shown in FIG. 12, in dummy electrode finger 121e, a part facing outermost electrode finger 11c and a part facing outermost electrode finger 11d may not be connected to each other. Also with this configuration, the difference of the propagation paths can be adjusted.

As mentioned above, an acoustic wave filter of the present invention has an effect of improving the degree of balance between signals output from a pair of balanced terminals, and is useful for electronic devices such as mobile telecommunication devices.

What is claimed is:

1. An acoustic wave filter, comprising:
an unbalanced terminal;
a first balanced terminal for outputting a signal of an opposite phase to a signal of the unbalanced terminal;
a second balanced terminal for outputting a signal of the same phase as a signal of the unbalanced terminal;
a first IDT electrode including first signal electrode fingers electrically connected to the unbalanced terminal and first ground electrode fingers electrically connected to ground, the first signal electrode fingers and the first ground electrode fingers being disposed alternately;
a second IDT electrode including second signal electrode fingers electrically connected to the first balanced terminal and second ground electrode fingers electrically connected to ground, the second signal electrode fingers and the second ground electrode fingers being disposed alternately; and
a third IDT electrode including third signal electrode fingers electrically connected to the second balanced terminal and third ground electrode fingers electrically connected to ground, the third signal electrode fingers and the third ground electrode fingers being disposed alternately,
wherein a dummy electrode finger electrically connected neither to the unbalanced terminal nor to the ground is provided on a side of the second IDT electrode in the first IDT electrode.

2. The acoustic wave filter of claim 1,
wherein a first outermost electrode finger on the side of the second IDT electrode in the first signal electrode fingers and a second outermost electrode finger on the side of the second IDT electrode in the first ground electrode fingers are provided such that they are not engaged with each other, and
the dummy electrode finger has an electrode part formed so as to face the first outermost electrode finger and the second outermost electrode finger, respectively.

3. The acoustic wave filter of claim 1, further comprising:
a fourth IDT electrode including fourth signal electrode fingers electrically connected to the unbalanced terminal, and fourth ground electrode fingers electrically connected to ground, the fourth signal electrode fingers and the fourth ground electrode fingers being disposed alternately, and
a fifth IDT electrode including fifth signal electrode fingers electrically connected to the unbalanced terminal and fifth ground electrode fingers electrically connected to ground, the fifth signal electrode fingers and the fifth ground electrode fingers being disposed alternately.
